(19) United States
(12) Patent Application Publication
(10) Pub. No.: US 2010/0248138 A1
(43) Pub. Date: Sep. 30, 2010

(54) LITHOGRAPHIC PRINTING PLATE PRECURSOR

(76) Inventor: Takanori MORI, Shizuoka (JP)

Correspondence Address: BIRCH STEWART KOLASCH & BIRCH, PO BOX 747, FALLS CHURCH, VA, 22040-0747, US

(21) Appl. No.: 12/723,108

(22) Filed: Mar. 12, 2010

(30) Foreign Application Priority Data
Mar. 27, 2009 (JP) P2009-079935

(51) Int. Cl. G03F 7/075; G03F 7/004

(52) U.S. Cl. 430/272.1; 430/271.1

(57) ABSTRACT

A lithographic printing plate precursor includes in the following order: a support; an image-recording layer containing (A) an infrared absorbing agent, (B) a polymerization initiator and (C) a polymerizable compound; and a protective layer, an unexposed area of the image-recording layer is capable of being removed with at least one of printing ink and dampening water on a printing machine, and the lithographic printing plate precursor contains a compound represented by the following formula (I):

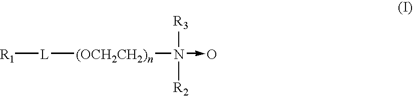

wherein R₁ represents an alkyl, alkenyl or aryl group having from 6 to 36 carbon atoms which may have a substituent, R₂ and R₃ each independently represents a methyl group, an ethyl group, a hydroxyethyl group or a hydroxypropyl group, L represents a single bond or a divalent connecting group, and n represents an integer of from 0 to 11.

### CROSS-REFERENCE TO RELATED APPLICATIONS

This application claims the benefit of Japanese Patent Application JP 2009-079935, filed Mar. 27, 2009, the entire content of which is hereby incorporated by reference, the same as if set forth at length.

### FIELD OF THE INVENTION

The present invention relates to a lithographic printing plate precursor capable of being subjected to image recording with laser and capable of being subjected to on-press development.

### BACKGROUND OF THE INVENTION

In general, a lithographic printing plate is composed of an oleophilic image area accepting ink and a hydrophilic non-image area accepting dampening water (fountain solution) in the process of printing. Lithographic printing is a printing method utilizing the nature of water and oily ink to repel with each other and comprising rendering the oleophilic image area of the lithographic printing plate to an ink-receptive area and the hydrophilic non-image area thereof to a dampening water-receptive area (ink-unreceptive area), thereby making a difference in adherence of the ink on the surface of the lithographic printing plate, depositing the ink only to the image area, and then transferring the ink to a printing material, for example, paper.

In order to produce the lithographic printing plate, a lithographic printing plate precursor (PS plate) comprising a hydrophilic support having provided thereon an oleophilic photosensitive resin layer (image-recording layer) is used. Specifically, the PS plate is exposed through a mask, for example, a lith film, and then subjected to development processing, for example, with an alkaline developer to remove the unnecessary image-recording layer corresponding to the non-image area by dissolving while leaving the image-recording layer corresponding to the image area, thereby obtaining the lithographic printing plate.

Due to the recent progress in the technical field, nowadays the lithographic printing plate can be obtained by a CTP (computer-to-plate) technology. Specifically, a lithographic printing plate precursor is directly subjected to scanning exposure using laser or laser diode without using a lith film and developed to obtain a lithographic printing plate.

With the progress described above, the issue on the lithographic printing plate precursor has transferred to improvements, for example, in image-forming property corresponding to the CTP technology, printing property or physical property. Also, with the increasing concern about global environment, as another issue on the lithographic printing plate precursor, an environmental problem on waste liquid discharged accompanying the wet treatment, for example, development processing comes to the front.

In response to the environmental problem, simplification of development or plate making or non-processing has been pursued. As one method of simple plate making, a method referred to as an “on-press development” is practiced. Specifically, according to the method after exposure of a lithographic printing plate precursor, the lithographic printing plate precursor is mounted as it is on a printing machine without conducting conventional development and removal of the unnecessary area of image-recording layer is performed at an early stage of printing step.

Also, as a method of simple development, a method referred to as a “gum development” is practiced wherein the removal of the unnecessary area of image-recording layer is performed using not a conventional high alkaline developer but a finisher or gum solution of near-neutral pH.

In the simplification of plate making operation as described above, a system using a lithographic printing plate precursor capable of being handled in a bright room or under a yellow lump and a light source is preferable from the standpoint of workability. Thus, as the light source, a semiconductor laser emitting an infrared ray having a wavelength of 760 to 1,200 or a solid laser, for example, YAG laser, is used. An UV laser is also used.

As the lithographic printing plate precursor capable of undergoing on-press development, for instance, a lithographic printing plate precursor having provided on a hydrophilic support, an image-recording layer (heat-sensitive layer) containing microcapsules having a polymerizable compound encapsulated therein is described in JP-A-2001-277740 (the term “JP-A” as used herein means an “unexamined published Japanese patent application”) and JP-A-2001-277742. A lithographic printing plate precursor having provided on a support, an image-recording layer (photosensitive layer) containing an infrared absorbing agent, a radical polymerization initiator and a polymerizable compound is described in JP-A-2002-287334. A lithographic printing plate precursor capable of undergoing on-press development having provided on a support, an image-recording layer containing a polymerizable compound and a graft polymer having a polyethylene oxide chain in its side chain or a block polymer having a polyethylene oxide block is described in U.S. Patent Publication No. 2003/0064318.

The methods using the polymerization reaction as described above have the feature that since the chemical bond density in the image area is high, the image strength is relatively good in comparison with the image area formed by the thermal fusion of fine polymer particles. However, it is necessary to provide a protective layer (overcoat layer) having an oxygen blocking property on the image-recording layer in order to prevent polymerization inhibition due to oxygen in the air or to prevent adhesion to a rear surface due to tackiness of the polymerizable compound.

It is conventionally known that a water-soluble resin, for example, polyvinyl alcohol is used in the protective layer for the purpose described above. A lithographic printing plate precursor of on-press development type provided with a protective layer using a modified polyvinyl alcohol is described in JP-A-2005-271284. Also, in order to increase the oxygen blocking property, incorporation of an inorganic stratiform compound, for example, mica into a protective layer is proposed in JP-A-2005-119273.

In the lithographic printing plate precursor of on-press development type, however, a problem arises in that initial ink receptivity at the start of printing is deteriorated by providing such a hydrophilic protective layer. Specifically, the protective layer is removed at development in plate making of a conventional lithographic printing plate precursor using an alkali developer. On the other hand, in case of plate making using on-press development, since the protective layer is present at the start of printing, due to high hydrophilicity of the protective layer ink does not attach to the image area until the protective layer is removed by the on-press development. The initial ink receptivity is further degraded when the protective layer contains the inorganic stratiform compound, for example, mica.

For the purpose of improving the initial ink receptivity, it is proposed to add an onium salt to the protective layer (see, for example, JP-A-2007-50660). It has been found, however, anew kind of problem arises in that the onium salt deposits in the protective layer or a coating solution for protective layer or deteriorates dispersion stability of the inorganic stratiform compound. In addition, the intended improvement in the initial ink receptivity is still insufficient for practical standpoint.

Further, a means for improving the initial ink receptivity by adding a quaternary ammonium compound to the image-recording layer is described in JP-A-2008-284858. Although the quaternary ammonium compound exhibits a large effect of improving the initial ink receptivity, it is found that since the quaternary ammonium compound has hydrophobicity, it adsorbs to interface of a support with the lapse of time to deteriorate on-press development property and to be liable to cause printing stain.

### SUMMARY OF THE INVENTION

An object of the present invention is to provide a lithographic printing plate precursor of on-press development type which provides good on-press development property after the preservation while maintaining sufficient printing durability and ink receptivity.

(1) A lithographic printing plate precursor which comprises a support having thereon an image-recording layer containing (A) an infrared absorbing agent, (B) a polymerization initiator and (C) a polymerizable compound and a protective layer and, optionally, an intermediate layer between the support and the image-recording layer, an unexposed area of the image-recording layer is capable of being removed with at least any one of printing ink and dampening water on a printing machine, and contains a compound represented by formula (I) shown below:

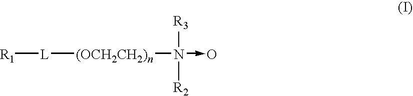

In formula (I), R₁ represents an alkyl, alkenyl or aryl group having from 6 to 36 carbon atoms which may have a substituent, R₂ and R₃ each independently represents a methyl group, an ethyl group, a hydroxyethyl group or a hydroxypropyl group, L represents a single bond or a divalent connecting group, and n represents an integer of 0 to 11.

(2) The lithographic printing plate precursor as described in (1) above, which comprises a support having thereon an image-recording layer containing (A) an infrared absorbing agent, (B) a polymerization initiator and (C) a polymerizable compound and a protective layer in this order, an unexposed area of the image-recording layer is capable of being removed with at least any one of printing ink and dampening water on a printing machine, and the image-recording layer contains a compound represented by formula (I) shown below:

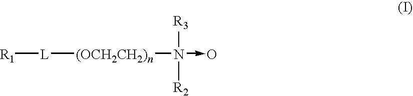

In formula (I), R₁ represents an alkyl, alkenyl or aryl group having from 6 to 36 carbon atoms which may have a substituent, R₂ and R₃ each independently represents a methyl group, an ethyl group, a hydroxyethyl group or a hydroxypropyl group, L represents a single bond or a divalent connecting group, and n represents an integer of 0 to 11.

(3) The lithographic printing plate precursor as described in (1) above, which comprises a support having thereon an inter mediate layer, an image-recording layer containing (A) an infrared absorbing agent, (B) a polymerization initiator and (C) a polymerizable compound and a protective layer in this order, an unexposed area of the image-recording layer is capable of being removed with at least any one of printing ink and dampening water on a printing machine, and at least one of the intermediate layer and image-recording layer contains the compound represented by formula (I).
(4) The lithographic printing plate precursor as described in anyone of (1) to (3) above, wherein n in the compound represented by formula (I) is 0.
(5) The lithographic printing plate precursor as described in anyone of (1) to (4) above, wherein the protective layer contains an inorganic particle.
(6) The lithographic printing plate precursor as described in (5) above, wherein the inorganic particle is mica.
(7) The lithographic printing plate precursor as described in (3) above, wherein the intermediate layer contains a copolymer containing (a1) a repeating unit having at least one ethylenically unsaturated bond and (a2) a repeating unit having at least one functional group capable of interacting with a surface of the support.

According to the present invention, a lithographic printing plate precursor of on-press development type which provides good on-press development property after the preservation while maintaining sufficient printing durability and ink receptivity can be provided.

### DETAILED DESCRIPTION OF THE INVENTION

### Lithographic Printing Plate Precursor

The lithographic printing plate precursor according to the invention comprises a support having thereon an image-recording layer and a protective layer. The lithographic printing plate precursor may also have an intermediate layer between the support and the image-recording layer according to the circumstances.

The constituting element, component and the like of the lithographic printing plate precursor according to the invention will be described below.

### (Image-Recording Layer)

The image-recording layer and/or intermediate layer for use in the invention is characterized by containing a nonionic compound represented by formula (I) shown below.

The image-recording layer capable of undergoing on-press development for use in the invention contains (A) an infrared absorbing agent, (B) a polymerization initiator and (C) a polymerizable compound and includes an image-forming embodiment of curing the exposed area utilizing a polymerization reaction. The image-recording layer may further contain (D) a hydrophobilizing precursor.

Each of the components constituting the image-recording layer will be described in order below.

### <Compound Represented by Formula (I)>

First, an amine oxide compound represented by formula (I) is described below.

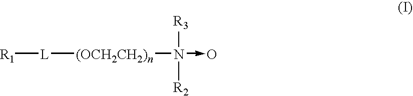

In formula (I), R₁ represents an alkyl, alkenyl or aryl group having from 6 to 36 carbon atoms which may have a substituent, preferably a straight-chain or branched alkyl group, and more preferably a straight-chain or branched alkyl group having from 6 to 24 carbon atoms.

Although not particularly restricted, a particularly useful group represented by R₁ includes a cyclohexyl group, a phenyl group, an alkyl group, for example, a dodecyl group, a tridecyl group, a tetradecyl group, a pentadecyl group, a hexadecyl group, an isopalmityl group, a heptadecyl group, an octadecyl group, an isostearyl group, an eicosyl group, a docosyl group, a tricosyl group, a tetracosyl group, a hexacosyl group, an octacosyl group, a triacontyl group, a dotriancontyl group, a 2-hexyldecyl group, a 2-(3-methylhexyl)-7-methyldecyl group, a 2-octyldecyl group, a 2-decyltetradecyl group or a 2-undecylpentadecyl group, an alkenyl group, for example, an oleyl group or a linolyl group, and a mixture of these groups, for example, a palm oil alkyl group, a beef tallow oil alkyl group or a cured beef tallow oil alkyl group.

Also, commercial products, for example, Catinal AOC, Softamine L and Softamine LD each produced by Toho Chemical Industry Co., Ltd., Softazolin LAO produced by Kawaken Fine Chemicals Co., Ltd., Amogen AOL produced by Dai-ichi Kogyo Seiyaku Co., Ltd., Taipolesoft AOC-30 produced by Taiko Oil Chemicals Co., Ltd., and Unisafe A-LM, Unisafe A-SM, Unisafe A-LE and Unisafe A-LY each produced by NOF Corp. are effectively used.

In the range where a number of carbon atoms included in R₁ is from 6 to 36, good ink receptivity is obtained.

n represents an integer of 0 to 11. In the range of n, good on-press development property and good ink receptivity are obtained. In order to achieve both interface adsorption property of the amine oxide group and oleophilicity of the hydrocarbon group, n is most preferably 0.

R₂ and R₃ each independently represents a methyl group, an ethyl group, a hydroxyethyl group or a hydroxypropyl group.

L represents a single bond or a divalent connecting group. When L is a divalent connecting group, the divalent connecting group is preferably constituted by from 1 to 60 carbon atoms, from 0 to 10 nitrogen atoms, from 0 to 50 oxygen atoms, from 1 to 100 hydrogen atoms and from 0 to 20 sulfur atoms.

More specifically, examples of the divalent connecting group include divalent groups shown below and divalent groups constituted by combination of these groups.

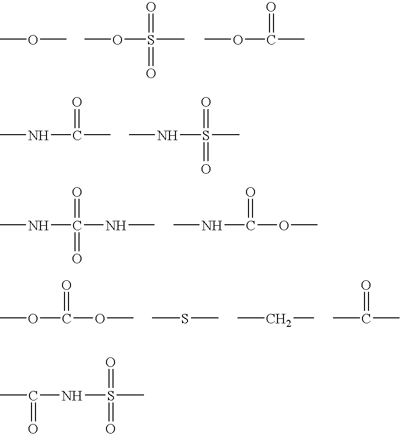

Specific examples of the compound represented by formula (I) are set forth below, but the invention should not be construed as being limited thereto.

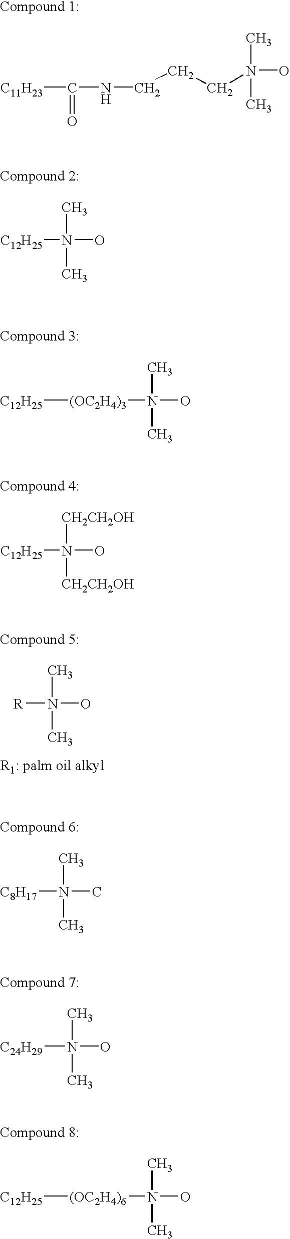

The content of the compound represented by formula (I) in the image-recording layer is preferably from 0.1 to 5% by weight, more preferably from 0.1 to 2.5% by weight, based on the total solid content of the image-recording layer. The content of the compound represented by formula (I) in the intermediate layer is preferably from 1 to 30% by weight, more preferably from 1 to 20% by weight, based on the total solid content of the intermediate layer.

The compound represented by formula (I) may further be added to a protective layer in addition to the incorporation into the image-recording layer and/or intermediate layer. The content of the compound represented by formula (I) in the protective layer is preferably 10% by weight or less based on the total solid content of the protective layer.

In the ranges described above, good on-press development property even after the preservation is obtained while maintaining sufficient printing durability and ink receptivity. The compounds represented by formula (I) may be sued individually or in combination of two or more thereof.

### <(A) Infrared Absorbing Agent>

The infrared absorbing agent has a function of converting the infrared ray absorbed to heat and a function of being excited by the infrared ray to perform electron transfer and/or energy transfer to a polymerization initiator described hereinafter. The infrared absorbing agent for use in the invention is a dye or pigment having an absorption maximum in a wavelength range of 760 to 1,200 nm.

As the infrared absorbing agent, compounds described in Paragraph Nos. [0058] to [0087] of JP-A-2008-195018 are used.

Of the infrared absorbing agents, cyanine dyes, squarylium dyes, pyrylium dyes and nickel thiolate complexes are particularly preferred. As the particularly preferable example of the dye, a cyanine dye represented by formula (a) shown below is exemplified.

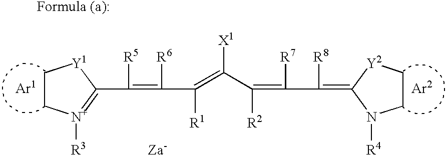

In formula (a), X¹ represents a hydrogen atom, a halogen atom, —N(R⁹)(R¹⁰), X²-L¹ or a group shown below. R⁹ and R¹⁰, which may be the same or different, each represents an aromatic hydrocarbon group having from 6 to 10 carbon atoms, which may have a substituent, an alkyl group having from 1 to 8 carbon atoms, which may have a substituent or a hydrogen atom, or R⁹ and R¹⁹ may be combined with each other to form a ring. Among them, a phenyl group is preferable. X² represents an oxygen atom or a sulfur atom, L¹ represents a hydrocarbon group having from 1 to 12 carbon atoms, an aromatic ring group containing a hetero atom or a hydrocarbon group having from 1 to 12 carbon atoms and containing a hetero atom. The hetero atom used herein indicates a nitrogen atom, a sulfur atom, an oxygen atom, a halogen atom and a selenium atom. In the group shown below, Xa⁻ has the same meaning as Za⁻ defined hereinafter, and R^{a} represents a hydrogen atom or a substituent selected from an alkyl group, an aryl group, a substituted or unsubstituted amino group and a halogen atom.

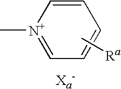

R¹ and R² each independently represents a hydrocarbon group having from 1 to 12 carbon atoms. In view of the preservation stability of a coating solution for image-recording layer, it is preferred that R¹ and R² each represents a hydrocarbon group having two or more carbon atoms. It is also preferred that R¹ and R² are combined with each other to form a 5-membered or 6-membered ring.

Ar¹ and Ar², which may be the same or different, each represents an aromatic hydrocarbon group which may have a substituent. Preferable examples of the aromatic hydrocarbon group include a benzene ring group and a naphthalene ring group. Also, preferable examples of the substituent include a hydrocarbon group having 12 or less carbon atoms, a halogen atom and an alkoxy group having 12 or less carbon atoms. Y¹ and Y², which may be the same or different, each represents a sulfur atom or a dialkylmethylene group having 12 or less carbon atoms. R³ and R⁴, which may be the same or different, each represents a hydrocarbon group having 20 or less carbon atoms, which may have a substituent. Preferable examples of the substituent include an alkoxy group having 12 or less carbon atoms, a carboxyl group and a sulfo group. R⁵, R⁶, R⁷ and R⁸, which may be the same or different, each represents a hydrogen atom or a hydrocarbon group having 12 or less carbon atoms. In view of the availability of raw materials, a hydrogen atom is preferred. Za⁻ represents a counter anion. However, Za⁻ is not necessary when the cyanine dye represented by formula (a) has an anionic substituent in the structure thereof and neutralization of charge is not needed. In view of the preservation stability of a coating solution for image-recording layer, preferable examples of the counter ion for Za⁻ include a halide ion, a perchlorate ion, a tetrafluoroborate ion, a hexafluorophosphate ion and a sulfonate ion, and particularly preferable examples thereof include a perchlorate ion, a hexafluorophosphate ion and an arylsulfonate ion.

Specific examples of the cyanine dye represented by formula (a), which can be preferably used in the invention, include those described in Paragraph Nos. [0017] to [0019] of JP-A-2001-133969, Paragraph Nos. [0012] to [0021] of JP-A-2002-23360 and Paragraph Nos. [0012] to [0037] of JP-A-2002-40638.

The infrared absorbing agents may be used individually or in combination of two or more thereof. In case of using in combination, a pigment may be used. As the pigment, compounds described in Paragraph Nos. [0072] to [0076] of JP-A-2008-195018 are preferably used.

The content of the infrared absorbing agent in the image-recording layer according to the invention is preferably from 0.1 to 10.0% by weight, more preferably from 0.5 to 5.0% by weight, based on the total solid content of the image-recording layer.

### <(B) Polymerization Initiator>

The polymerization initiator (B) for use in the invention is a compound which initiates or accelerates polymerization of the polymerizable compound (C). The polymerization initiator for use in the invention is preferably a radical polymerization initiator and includes, for example, known thermal polymerization initiators, compounds containing a bond having small bond dissociation energy and photopolymerization initiators.

The radical polymerization initiators in the invention include, for example, (a) organic halides, (b) carbonyl compounds, (c) azo compounds, (d) organic peroxides, (e) metallocene compounds, (f) azido compounds, (g) hexaarylbiimidazole compounds, (h) organic borate compounds, (i) disulfone compounds, (j) oxime ester compounds and (k) onium salt compounds.

As the organic halides (a), compounds described in Paragraph Nos. [0022] to [0023] of JP-A-2008-195018 are preferable.

As the carbonyl compounds (b), compounds described in Paragraph No. [0024] of JP-A-2008-195018 are preferable.

As the azo compounds (c), for example, azo compounds described in JP-A-8-108621 are used.

As the organic peroxides (d), for example, compounds described in Paragraph No. [0025] of JP-A-2008-195018 are preferable.

As the metallocene compounds (e), for example, compounds described in Paragraph No. [0026] of JP-A-2008-195018 are preferable.

As the azido compounds (f), compound, for example, 2,6-bis(4-azidobenzylidene)-4-methylcyclohexanone is exemplified.

As the hexaarylbiimidazole compounds (g), for example, compounds described in Paragraph No. [0027] of JP-A-2008-195018 are preferable.

As the organic borate compounds (h), for example, compounds described in Paragraph No. [0028] of JP-A-2008-195018 are preferable.

As the disulfone compounds (I), for example, compounds described in JP-A-61-166544 and JP-A-2003-328465 are exemplified.

As the oxime ester compounds (j), for example, compounds described in Paragraph Nos. [0028] to [0030] of JP-A-2008-195018 are preferable.

As the onium salt compounds (k), onium salts, for example, diazonium salts described in S. I. Schlesinger, Photogr. Sci. Eng., 18, 387 (1974) and T. S. Bal et al., Polymer, 21, 423 (1980), ammonium salts described in U.S. Pat. No. 4,069,055 and JP-A-4-365049, phosphonium salts described in U.S. Pat. Nos. 4,069,055 and 4,069,056, iodonium salts described in European Patent 104,143, U.S. Patent Publication No. 2008/0311520 and JP-A-2-150848, sulfonium salts described in European Patents 370,693, 390,214, 233,567, 297,443 and 297,442, U.S. Pat. Nos. 4,933,377, 4,760,013, 4,734,444 and 2,833,827 and German Patents 2,904,626, 3,604,580 and 3,604,581, selenonium salts described in J. V. Crivello et al., Macromolecules, 10 (6), 1307 (1977) and J. V. Crivello et al., J. Polymer Sci., Polymer Chem. Ed., 17, 1047 (1979), arsonium salts described in C. S. Wen et al., Teh, Proc. Conf. Rad. Curing ASIA, p. 478, Tokyo, Oct. (1988), and azinium salts described in JP-A-2008-195018 are exemplified.

Of the radical polymerization initiators, the onium salts, particularly, the iodonium salts, sulfonium salts and azinium salts are preferable. Specific examples of these compounds are set forth below, but the invention should not be construed as being limited thereto.

Of the iodonium salts, a diphenyliodonium salt is preferable, a diphenyliodonium salt substituted with an electron donating group, for example, an alkyl group or an alkoxy group is more preferable, and an asymmetric diphenyliodonium salt is still more preferable. Examples of the iodonium salt include diphenyliodonium hexafluorophosphate, 4-methoxyphenyl-4-(2-methylpropyl)phenyliodonium hexafluorophosphate, 4-(2-methylpropyl)phenyl-p-tolyliodonium hexafluorophosphate, 4-hexyloxyphenyl-2,4,6-trimethoxyphenyliodonium hexafluorophosphate, 4-hexyloxyphenyl-2,4-diethoxyphenyliodoniumtetraphenylborate, 4-octyloxyphenyl-2,4,6-trimethoxyphenyliodonium 1-perfluorobutanesulfonate, 4-octyloxyphenyl-2,4,6-trimethoxyphenyliodonium hexafluorophosphate and bis(4-tert-butylphenyl)iodonium tetraphenylborate.

Examples of the sulfonium salt include triphenylsulfonium hexafluorophosphate, triphenylsulfonium benzoylformate, bis(4-chlorophenyl)phenylsulfonium benzoylformate, bis(4-chlorophenyl)-4-methylphenylsulfonium tetrafluoroborate and tris(4-chlorophenyl)sulfonium 3,5-bis(methoxycarbonyl)benzenesulfonate.

Examples of the azinium salt include 1-cyclohexylmethyloxypyridinium hexafluorophosphate, 1-cyclohexyloxy-4-phenylpyridinium hexafluorophosphate, 1-ethoxy-4-phenylpyridinium hexafluorophosphate, 1-(2-ethylhexyloxy)-4-phenylpyridinium hexafluorophosphate, 4-chloro-1-cyclohexylmethyloxypyridinium hexafluorophosphate, 1-ethoxy-4-cyanopyridinium hexafluorophosphate, 3,4-dichloro-1-(2-ethylhexyloxy)pyridinium hexafluorophosphate, 1-benzyloxy-4-phenylpyridinium hexafluorophosphate, 1-phenethyloxy-4-phenylpyridinium hexafluorophosphate, 1-(2-ethylhexyloxy)-4-phenylpyridinium p-toluenesulfonate, 1-(2-ethylhexyloxy)-4-phenylpyridinium perfluorobutanesulfonate, 1-(2-ethylhexyloxy)-4-phenylpyridinium bromide and 1-(2-ethylhexyloxy)-4-phenylpyridinium tetrafluoroborate.

The polymerization initiator can be added to the image-recording layer preferably in an amount from 0.1 to 50% by weight, more preferably from 0.5 to 30% by weight, particularly preferably from 0.8 to 20% by weight, based on the total solid content constituting the image-recording layer. In the range described above, good sensitivity and good stain resistance in the non-image area at the time of printing are obtained.

### <(C) Polymerizable Compound>

The polymerizable compound for use in the invention is an addition-polymerizable compound having at least one ethylenically unsaturated double bond, and it is preferably selected from compounds having at least one, preferably two or more, terminal ethylenically unsaturated double bonds. Such compounds are widely known in the field of art and they can be used in the invention without any particular limitation. The compound has a chemical form, for example, amonomer, aprepolymer, specifically, a dimer, a trimer or an oligomer, or a (co)polymer thereof, or a mixture thereof.

Specific examples of the polymerizable compound include compounds described in Paragraph Nos. [0089] to [0098] of JP-A-2008-195018. Among them, esters of aliphatic polyhydric alcohol compound with an unsaturated carboxylic acid (for example, acrylic acid, methacrylic acid, itaconic acid, crotonic acid, isocrotonic acid or maleic acid) are preferably exemplified. Other preferable polymerizable compound includes polymerizable compounds containing an isocyanuric acid structure described in JP-A-2005-329708.

Among them, isocyanuric acid ethylene oxide-modified acrylates, for example, tris(acryloyloxyethyl)isocyanurate or bis(acryloyloxyethyl)hydroxyethyl isocyanurate are particularly preferable.

The polymerizable compound is preferably used in an amount from 5 to 80% by weight, more preferably from 25 to 75% by weight, based on the total solid content of the image-recording layer.

### <(D) Hydrophobilizing Precursor>

According to the invention, a hydrophobilizing precursor can be used in order to improve the on-press development property. The hydrophobilizing precursor for use in the invention is a fine particle capable of converting the image-recording layer to be hydrophobic when heat is applied. The fine particle is preferably at least one fine particle selected from hydrophobic thermoplastic polymer fine particle, thermo-reactive polymer fine particle, microcapsule having a hydrophobic compound encapsulated and microgel (crosslinked polymer fine particle). Among them, polymer fine particle having a polymerizable group and microgel are preferable.

As the hydrophobic thermoplastic polymer fine particle, hydrophobic thermoplastic polymer fine particles described, for example, in Research Disclosure, No. 33303, January (1992), JP-A-9-123387, JP-A-9-131850, JP-A-9-171249, JP-A-9-171250 and European Patent 931,647 are preferably exemplified.

Specific examples of the polymer constituting the polymer fine particle include a homopolymer or copolymer of a monomer, for example, ethylene, styrene, vinyl chloride, methyl acrylate, ethyl acrylate, methyl methacrylate, ethyl methacrylate, vinylidene chloride, acrylonitrile, vinyl carbazole or an acrylate or methacrylate having a polyalkylene structure and a mixture thereof. Among them, polystyrene, copolymer containing styrene and acrylonitrile and polymethyl methacrylate are more preferable.

The average particle size of the hydrophobic thermoplastic polymer fine particle for use in the invention is preferably from 0.01 to 2.0 μm.

The thermo-reactive polymer fine particle for use in the invention includes a polymer fine particle having a thermo-reactive group and forms a hydrophobilized region by crosslinkage due to thermal reaction and change in the functional group involved therein.

As the thermo-reactive group of the polymer fine particle having a thermo-reactive group for use in the invention, a functional group performing any reaction can be used as long as a chemical bond is formed. For instance, an ethylenically unsaturated group (for example, an acryloyl group, a methacryloyl group, a vinyl group or an allyl group) performing a radical polymerization reaction, a cationic polymerizable group (for example, a vinyl group or a vinyloxy group), an isocyanate group performing an addition reaction or a blocked form thereof, an epoxy group, a vinyloxy group and a functional group having an active hydrogen atom (for example, an amino group, a hydroxy group or a carboxyl group) as the reaction partner thereof, a carboxyl group performing a condensation reaction and a hydroxyl group or an amino group as the reaction partner thereof, and an acid anhydride performing a ring opening addition reaction and an amino group or a hydroxyl group as the reaction partner thereof are preferably exemplified.

As the microcapsule for use in the invention, microcapsule having all or part of the constituting components of the image-recording layer encapsulated as described, for example, in JP-A-2001-277740 and JP-A-2001-277742 is exemplified. The constituting components of the image-recording layer may be present outside the microcapsules. It is a more preferable embodiment of the image-recording layer containing microcapsules that hydrophobic constituting components are encapsulated in microcapsules and hydrophilic components are present outside the microcapsules.

The image-recording layer according to the invention is an embodiment containing a crosslinked resin particle, that is, a microgel. The microgel can contain a part of the constituting components of the image-recording layer inside and/or on the surface thereof. Particularly, an embodiment of a reactive microgel containing the polymerizable compound on the surface thereof is preferable in view of the image-forming sensitivity and printing durability.

As a method of microencapsulation or microgelation of the constituting components of the image-recording layer, known methods can be used.

The average particle size of the microcapsule or microgel is preferably from 0.01 to 3.0 μm, more preferably from 0.05 to 2.0 μm, particularly preferably from 0.10 to 1.0 μm. In the range described above, good resolution and good time-lapse stability can be achieved.

The content of the hydrophobilizing precursor is preferably in a range of 5 to 90% by weight based on total solid content of the image-recording layer.

### <(E) Other Components>

The image-recording layer according to the invention may further contain other components, if desired.

In the image-recording layer according to the invention, a binder polymer can be used for the purpose of improving film strength of the image-recording layer. The binder polymer which can be used in the invention can be selected from those heretofore known without restriction, and polymers having a film-forming property are preferable. Among them, acrylic resins, polyvinyl acetal resins and polyurethane resins are preferable.

As the binder polymer preferable for the invention, a polymer having a crosslinkable functional group for improving film strength of the image area in its main chain or side chain, preferably in its side chain, as described in JP-A-2008-195018 is exemplified. Due to the crosslinkable functional group, crosslinkage is formed between the polymer molecules to facilitate curing.

As the crosslinkable functional group, an ethylenically unsaturated group, for example, a (meth) acryl group, a vinyl group or an allyl group or an epoxy group is preferable. The crosslinkable functional group can be introduced into the polymer by a polymer reaction or copolymerization. For instance, a reaction between an acrylic polymer or polyurethane having a carboxyl group in its side chain and glycidyl methacrylate or a reaction between a polymer having an epoxy group and a carboxylic acid containing an ethylenically unsaturated group, for example, methacrylic acid can be utilized.

The content of the crosslinkable group in the binder polymer is preferably from 0.1 to 10.0 mmol, more preferably from 1.0 to 7.0 mmol, most preferably from 2.0 to 5.5 mmol, based on 1 g of the binder polymer.

It is also preferred that the binder polymer for use in the invention further contains a hydrophilic group. The hydrophilic group contributes to impart the on-press development property to the image-recording layer. In particular, coexistence of the crosslinkable group and the hydrophilic group makes it possible to maintain good balance between printing durability and developing property.

The hydrophilic group includes, for example, a hydroxy group, a carboxyl group, an alkylene oxide structure, an amino group, an ammonium group, an amido group, a sulfo group and a phosphoric acid group. Among them, an alkylene oxide structure containing from 1 to 9 alkylene oxide units having 2 or 3 carbon atoms is preferable. In order to introduce a hydrophilic group into the binder polymer, a monomer having the hydrophilic group is copolymerized.

In order to control the ink-receptive property, an oleophilic group, for example, an alkyl group, an aryl group, an aralkyl group or an alkenyl group may be introduced into the binder polymer according to the invention. Specifically, an oleophilic group-containing monomer, for example, an alkyl methacrylate is copolymerized.

Specific examples (1) to (11) of the binder polymer for use in the invention are set forth below, but the invention should not be construed as being limited thereto.

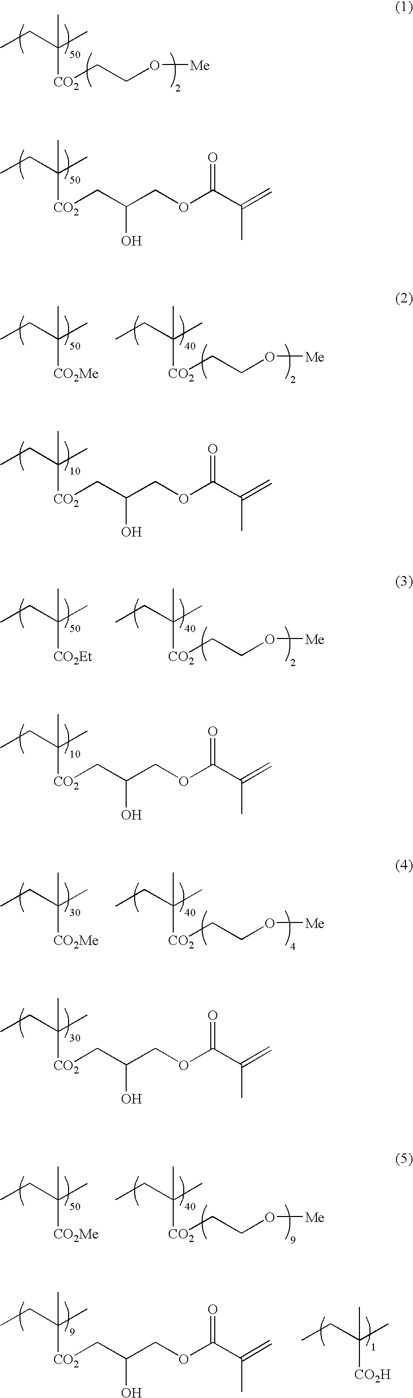

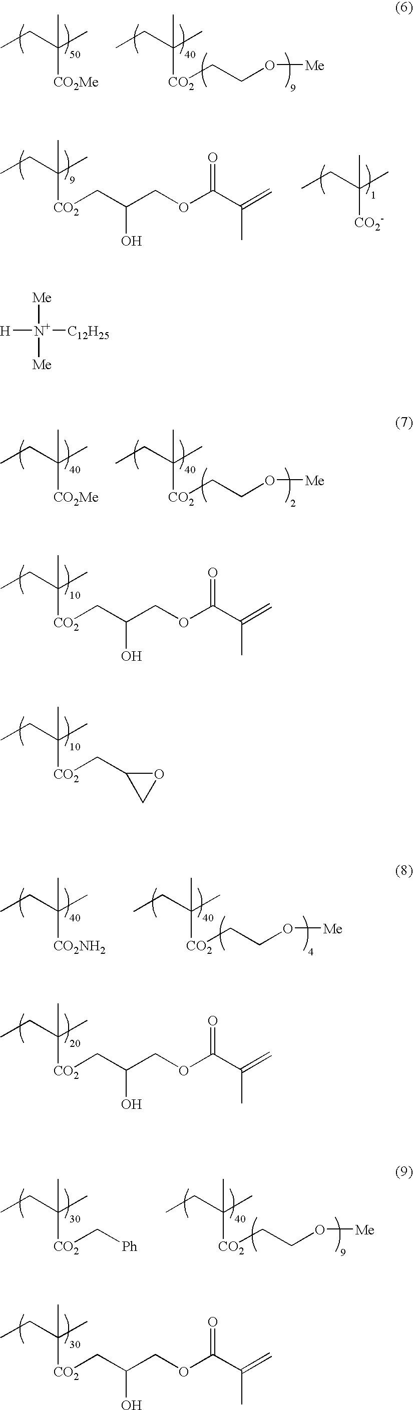

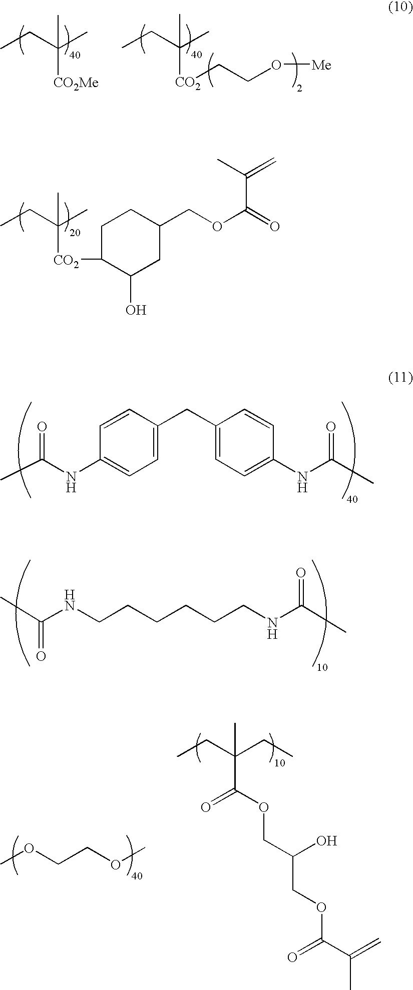

The weight average molecular weight (Mw) of the binder polymer according to the invention is preferably 2,000 or more, more preferably 5,000 or more, and still more preferably from 10,000 to 300,000.

According to the invention, a hydrophilic polymer, for example, polyacrylic acid or polyvinyl alcohol described in JP-A-2008-195018 may be used, if desired. Further, an oleophilic binder polymer is used together with a hydrophilic binder polymer.

The content of the binder polymer is preferably from 5 to 90% by weight, more preferably from 5 to 80% by weight, further more preferably from 10 to 70% by weight, based on the total solid content of the image-recording layer.

### (2) Hydrophilic Low Molecular Weight Compound

The image-recording layer according to the invention may contain a hydrophilic low molecular weight compound in order to improve the on-press development property without accompanying the decrease in the printing durability.

The hydrophilic low molecular weight compound includes a water-soluble organic compound, for example, a glycol compound, e.g., ethylene glycol, diethylene glycol, triethylene glycol, propylene glycol, dipropylene glycol or tripropylene glycol, or an ether or ester derivative thereof, a polyhydroxy compound, e.g., glycerine, pentaerythritol or tris(2-hydroxyethyl)isocyanurate, an organic amine compound, e.g., triethanol amine, diethanol amine or monoethanol amine, or a salt thereof, an organic sulfonic acid compound, e.g., an alkyl sulfonic acid, toluene sulfonic acid or benzene sulfonic acid, or a salt thereof, an organic sulfamic acid compound, e.g., an alkyl sulfamic acid, or a salt thereof, an organic sulfuric acid compound, e.g., an alkyl sulfuric acid or an alkyl ether sulfuric acid, or a salt thereof, an organic phosphonic acid compound, e.g., phenyl phosphonic acid, or a salt thereof, an organic carboxylic acid, e.g., tartaric acid, oxalic acid, citric acid, malic acid, lactic acid, gluconic acid or an amino acid, or a salt thereof and a betaine compound.

According to the invention, it is preferred that at least one compound selected from a polyol compound, an organic sulfate compound, an organic sulfonate compound and a betaine compound is incorporated.

Specific examples of the organic sulfonate compound include an alkylsulfonate, for example, sodium n-butylsulfonate, sodium n-hexylsulfonate, sodium 2-ethylhexylsulfonate, sodium cyclohexylsulfonate or sodium n-octylsulfonate; an alkylsulfonate containing an ethylene oxide chain, for example, sodium 5,8,11-trioxapentadecane-1-sulfate, sodium 5,8,11-trioxaheptadecane-1-sulfate, sodium 13-ethyl-5,8,11-trioxaheptadecane-1-sulfate or sodium 5,8,11,14-tetraoxatetracosane-1-sulfate; and an arylsulfonate, for example, sodium benzenesulfonate, sodium p-toluenesulfonate, sodium p-hydroxybenzenesulfonate, sodium p-styrenesulfonate, sodium isophthalic acid dimethyl-5-sulfonate, sodium 1-naphtylsulfonate, sodium 4-hydroxynaphtylsulfonate, disodium 1,5-naphtyldisulfonate or trisodium 1,3,6-naphtyltrisulfonate. The salt may also be potassium salt or lithium salt.

The organic sulfate compound includes a sulfate of alkyl, alkenyl, alkynyl, aryl or heterocyclic monoether of polyethylene oxide. The number of unit of ethylene oxide is preferably from 1 to 4. The salt is preferably a sodium salt, a potassium salt or a lithium salt.

As the betaine compound, a compound wherein a number of carbon atoms included in a hydrocarbon substituent on the nitrogen atom is from 1 to 5 is preferable. Specific examples thereof include trimethylammonium acetate, dimethylpropylammonium acetate, 3-hydroxy-4-trimethylammoniobutyrate, 4-(1-pyridinio)butyrate, 1-hydroxyethyl-1-imidazolioacetate, trimethylammonium methanesulfonate, dimethylpropylammonium methanesulfonate, 3-trimethylammonio-1-porpanesulfonate and 3-(1-pyridinio)-1-porpanesulfonate.

Since the hydrophilic low molecular weight compound has a small structure of hydrophobic portion and almost no surface active function, degradations of the hydrophobicity and film strength in the image area due to penetration of dampening water into the exposed area (image area) of the image-recording layer are prevented and thus, the ink receptive-property and printing durability of the image-recording layer can be preferably maintained.

The amount of the hydrophilic low molecular weight compound added to the image-recording layer is preferably from 0.5 to 20% by weight, more preferably from 1 to 10% by weight, still more preferably from 2 to 8% by weight, based on the total solid content of the image-recording layer. In the range described above, good on-press development property and good printing durability are achieved.

The hydrophilic low molecular weight compounds may be used individually or as a mixture of two or more thereof.

### (3) Other Components

Other components, for example, a surfactant, a coloring agent, a print-out agent, a polymerization inhibitor, a higher fatty acid derivative, a plasticizer, a fine inorganic particle, an inorganic stratiform compound, a co-sensitizer or a chain transfer agent may further be added to the image-recording layer. Specifically, compounds and amounts added thereof described, for example, in Paragraph Nos. [0114] to [0159] of JP-A-2008-284817, Paragraph Nos. [0023] to [0027] of JP-A-2006-91479 and Paragraph No. [0060] of U.S. Patent Publication No. 2008/0311520 are preferably used.

### <(F) Formation of Image-Recording Layer>

The image-recording layer according to the invention is formed by dispersing or dissolving each of the necessary constituting components described above in a solvent to prepare a coating solution and coating the solution on a support by a known method, for example, bar coater coating and drying as described in Paragraph Nos. [0142] to [0143] of JP-A-2008-195018. The coating amount (solid content) of the image-recording layer formed on a support after coating and drying may be varied according to the intended purpose but is in general preferably from 0.3 to 3.0 g/m². In the range described above, good sensitivity and good film property of the image-recording layer can be achieved.

### (Intermediate Layer)

In the lithographic printing plate precursor according to the invention, an intermediate layer (also referred to as an undercoat layer) is preferably provided between the image-recording layer and the support. The intermediate layer strengthens adhesion between the support and the image-recording layer in the exposed area and makes removal of the image-recording layer from the support in the unexposed area easy, thereby contributing improvement in the developing property without accompanying degradation of the printing durability. Further, it is advantageous that in the case of infrared laser exposure, since the intermediate layer acts as a heat insulating layer, decrease in sensitivity due to diffusion of heat generated upon the exposure into the support is prevented.

As a compound for use in the intermediate layer, specifically, for example, a silane coupling agent having an addition-polymerizable ethylenic double bond reactive group described in JP-A-10-282679 and a phosphorus compound having an ethylenic double bond reactive group described in JP-A-2-304441 are preferably exemplified. A copolymer having (a1) a repeating unit containing at least one ethylenically unsaturated bond and (a2) a repeating unit containing at least one functional group capable of interacting with a surface of the support as described in JP-A-2005-125749 is more preferably exemplified. The copolymer preferably further has a repeating unit containing a hydrophilic group. Such a copolymer is preferably a copolymer of a monomer having a functional group (adsorbing group) capable of interacting with a surface of the support, a monomer having a hydrophilic group and a monomer having an ethylenically unsaturated bond. More specifically, a copolymer of a monomer having an adsorbing group, for example, a phenolic hydroxy group, a carboxyl group, —PO₃H₂, —OPO₃H₂, —CONHSO₂—, —SO₂NHSO₂— or —COCH₂COCH₃, a monomer having a hydrophilic sulfo group and a monomer having a polymerizable group, for example, a methacryl group or an allyl group. The copolymer may contain a polymerizable group introduced by a salt formation between a polar substituent in the copolymer and a compound containing a substituent having a counter charge to the polar substituent in the copolymer and an ethylenically unsaturated bond, and it also may further be copolymerized with a monomer other than those described above, preferably a hydrophilic monomer.

Specific examples of the copolymer include copolymers described in JP-A-2005-125749 and JP-A-2006-188038.

The content of the unsaturated double bond in the copolymer for intermediate layer is preferably from 0.1 to 10.0 mmol, most preferably from 2.0 to 5.5 mmol, based on 1 g of the copolymer.

The weight average molecular weight of the copolymer for intermediate layer is preferably 5,000 or more, and more preferably from 10,000 to 300,000.

The intermediate layer according to the invention may contain a chelating agent, a secondary or tertiary amine, a polymerization inhibitor or a compound containing an amino group or a functional group having polymerization inhibition ability and a group capable of interacting with a surface of aluminum support (for example, 1,4-diazobicyclo[2,2,2]octane (DABCO), 2,3,5,6-tetrahydroxy-p-quinone, chloranil, sulfophthalic acid, hydroxyethylethylenediaminetriacetic acid, dihydroxyethylethylenediaminediacetic acid or hydroxyethyliminodiacetic acid) in addition to the compounds for the intermediate layer described above in order to prevent the occurrence of stain due to preservation of the lithographic printing plate precursor.

The intermediate layer is coated according to a known method. The coating amount (solid content) of the intermediate layer is preferably from 0.1 to 100 mg/m², and more preferably from 1 to 30 mg/m².

### (Support)

As the support for use in the lithographic printing plate precursor according to the invention, a known support is used. Particularly, an aluminum plate subjected to roughening treatment and anodizing treatment according to a known method is preferable.

Also, other treatments, for example, an enlarging treatment or a sealing treatment of micropores of the anodized film described in JP-A-2001-253181 and JP-A-2001-322365 or a surface hydrophilizing treatment, for example, with an alkali metal silicate as described in U.S. Pat. Nos. 2,714,066, 3,181,461, 3,280,734 and 3,902,734 or polyvinyl phosphonic acid as described in U.S. Pat. Nos. 3,276,868, 4,153,461 and 4,689,272 may be appropriately selected and applied to the aluminum plate, if desired.

The support preferably has a center line average roughness of 0.10 to 1.2 μm.

The support may have a backcoat layer containing an organic polymer compound described in JP-A-6-35174 or an alkoxy compound of silicon described in JP-A-6-35174, provided on the back surface thereof, if desired.

### (Protective Layer)

In the lithographic printing plate precursor according to the invention, it is preferred to provide a protective layer (overcoat layer) on the image-recording layer. The protective layer has a function for preventing, for example, occurrence of scratch in the image-recording layer or ablation caused by exposure with a high illuminance laser beam, in addition to the function for restraining an inhibition reaction against the image formation by means of oxygen blocking.

With respect to the protective layer having such properties, there are described, for example, in U.S. Pat. No. 3,458,311 and JP-B-55-49729 (the term “JP-B” as used herein means an “examined Japanese patent publication”). As a polymer having low oxygen permeability for use in the protective layer, any water-soluble polymer and water-insoluble polymer can be appropriately selected to use. Specifically, for example, polyvinyl alcohol, a modified polyvinyl alcohol, polyvinyl pyrrolidone, a water-soluble cellulose derivative and poly(meth)acrylonitrile are exemplified.

It is preferred to incorporate an inorganic particle into the protective layer of the lithographic printing plate precursor according to the invention. As the inorganic particle to be incorporated, an inorganic stratiform compound is preferable. The inorganic stratiform compound is a particle having a thin tabular shape and includes, for instance, mica, for example, natural mica represented by the following formula:

A(B,C)₂₋₅D₄O₁₀(OH,F,O)₂

(wherein A represents any one of K, Na and Ca, B and C each represents any one of Fe (II), Fe(III), Mn, Al, Mg and V, and D represents Si or Al) or synthetic mica, talc represented by the following formula: 3MgO.4SiO.H₂O, teniolite, montmorillonite, saponite, hectolite and zirconium phosphate.

Of the micas, examples of the natural mica include muscovite, paragonite, phlogopite, biotite and lepidolite. Examples of the synthetic mica include non-swellable mica, for example, fluorphlogopite KMg₃(AlSi₃O₁₀)F₂ or potassium tetrasilic mica KMg_{2.5}(Si₄O₁₀)F₂, and swellable mica, for example, Na tetrasilic mica NaMg_{2.5}(Si₄O₁₀)F₂, Na or Li teniolite (Na, Li)Mg₂Li(Si₄O₁₀)F₂, or montmorillonite based Na or Li hectolite (Na, Li)_{1/8}Mg_{2/5}Li_{1/8}(Si₄O₁₀)F₂. Synthetic smectite is also useful.

Of the inorganic stratiform compounds, fluorine-based swellable mica, which is a synthetic inorganic stratiform compound, is particularly useful in the invention. Specifically, the swellable synthetic mica and an swellable clay mineral, for example, montmorillonite, saponite, hectolite or bentonite have a stratiform structure comprising a unit crystal lattice layer having thickness of approximately 10 to 15 angstroms, and metallic atom substitution in the lattices thereof is remarkably large in comparison with other clay minerals. As a result, the lattice layer results in lack of positive charge and to compensate it, a cation, for example, Li⁺, Na⁺, Ca²⁺ or Mg²⁺ is adsorbed between the lattice layers. The cation present between the layers is referred to as an exchangeable cation and can be exchanged with various cations. When the cation present between the layers is Li⁺ or Na⁺, since the ion radius thereof is small, a bond between the stratiform crystal lattices is week and greatly swells with water. When share is applied under such condition, the stratiform crystal lattices are easily cleaved to form a stable sol in water. The bentnite and swellable synthetic mica have strongly such tendency and useful in the invention. In particular, the swellable synthetic mica is preferably used.

With respect to the shape of the stratiform compound for use in the invention, the thinner the thickness or the larger the plain size as long as smoothness of coated surface and transmission of actinic radiation are not damaged, the better from the standpoint of control of diffusion. Therefore, an aspect ratio of the stratiform compound is ordinarily 20 or more, preferably 100 or more, and particularly preferably 200 or more. The aspect ratio is a ratio of major axis to thickness of particle and can be determined, for example, from a projection drawing of particle by a microphotography. The larger the aspect ratio, the greater the effect obtained.

As for the particle diameter of the inorganic stratiform compound for use in the invention, an average major axis is ordinarily from 0.3 to 20 μm, preferably from 0.5 to 10 μm, and particularly preferably from 1 to 5 μm. An average thickness of the particle is ordinarily 0.1 μm or less, preferably 0.05 μm or less, and particularly preferably 0.01 μm or less. For example, with respect to the swellable synthetic mica that is the representative compound of the inorganic stratiform compounds, the thickness is approximately from 1 to 50 nm and the plain size is approximately from 1 to 20 μm.

When such an inorganic stratiform compound particle having a large aspect ratio is incorporated into the protective layer, strength of the coated layer increases and penetration of oxygen or moisture can be effectively inhibited so that the protective layer can be prevented from deterioration due to deformation, and even when the lithographic printing plate precursor is preserved for a long period of time under a high humidity condition, it is prevented from decrease in the image-forming property thereof due to the change of humidity and exhibits excellent preservation stability.

The content of the inorganic stratiform compound in the protective layer is ordinarily from 5/1 to 1/100 in terms of a weight ratio of the inorganic stratiform compound to an amount of a binder used in the protective layer. When a plural kind of the inorganic stratiform compounds is used together, it is preferred that the total amount of the inorganic stratiform compounds is in the range of weight ratio described above.

The protective layer according to the invention may also contain a spherical fine inorganic particle for the purpose of controlling a slipping property of the uppermost surface of the lithographic printing plate precursor. The fine inorganic particle preferably includes, for example, silica, alumina, magnesium oxide, titanium oxide, magnesium carbonate, calcium alginate and a mixture thereof. The fine inorganic particle preferably has an average particle size from 5 nm to 10 μm, and more preferably from 50 nm to 3 μm. The fine inorganic particle described above is easily available as a commercial product, for example, colloidal silica dispersion.

The content of the fine inorganic particle is preferably 40% by weight or less, more preferably 20% by weight or less, based on the total solid content of the protective layer.

Ordinarily, the exposure is performed in the air in the invention. The protective layer prevents the low molecular weight compound, for example, oxygen or a basic substance present in the air, which inhibits the image-forming reaction occurred upon the exposure in the image-recording layer and as a result, the inhibition of image-forming reaction at the exposure in the air can be restrained. Accordingly, the property required of the protective layer is to reduce permeability of the low molecular compound, for example, oxygen. Further, the protective layer preferably has good transparency to light used for the exposure, is excellent in an adhesion property to the image-recording layer, and can be easily removed during the on-press development processing step after the exposure. With respect to the protective layer having such properties, there are described, for example, in U.S. Pat. No. 3,458,311 and JP-B-55-49729.

Further, the protective layer may contain a known additive, for example, a plasticizer for imparting flexibility, a surfactant for improving a coating property or a fine inorganic particle for controlling a surface slipping property. The oil-sensitizing agent described with respect to the image-recording layer may also be incorporated into the protective layer.

The protective layer is coated according to a known method. The coating amount of the protective layer is preferably in a range of 0.01 to 10 g/m², more preferably in a range of 0.02 to 3 g/m², most preferably in a range of 0.02 to 1 g/m², in terms of the coating amount after drying.

### [Plate Making Method]

Plate making of the lithographic printing plate precursor according to the invention is preferably performed by an on-press development method. The on-press development method includes a step in which the lithographic printing plate precursor is imagewise exposed and a printing step in which oily ink and an aqueous component are supplied to the exposed lithographic printing plate precursor without undergoing any development processing to perform printing, and it is characterized in that the unexposed area of the lithographic printing plate precursor is removed in the course of the printing step. The imagewise exposure may be performed on a printing machine after the lithographic printing plate precursor is mounted on the printing machine or may be separately performed using a platesetter or the like. In the latter case, the exposed lithographic printing plate precursor is mounted as it is on a printing machine without undergoing a development processing step. Then, the printing operation is initiated using the printing machine with supplying oily ink and an aqueous component and at an early stage of the printing the on-press development is carried out. Specifically, the image-recording layer in the unexposed area is removed and the hydrophilic surface of support is revealed therewith to form the non-image area. As the oily ink and aqueous component, printing ink and dampening water for conventional lithographic printing can be employed, respectively.

The on-press development method is described in more detail below.

As the light source used for the image exposure in the invention, a laser is preferable. The laser for use in the invention is not particularly restricted and includes, for example, a solid laser or semiconductor laser emitting an infrared ray having a wavelength of 760 to 1,200 nm.

With respect to the infrared ray laser, the output is preferably 100 mW or more, the exposure time per pixel is preferably within 20 microseconds, and the irradiation energy is preferably from 10 to 300 mJ/cm². With respect to the laser exposure, in order to shorten the exposure time, it is preferred to use a multibeam laser device.

The exposed lithographic printing plate precursor is mounted on a plate cylinder of a printing machine. In case of using a printing machine equipped with a laser exposure apparatus, the lithographic printing plate precursor is mounted on a plate cylinder of the printing machine and then subjected to the imagewise exposure.

When dampening water and printing ink are supplied to the imagewise exposed lithographic printing plate precursor to perform printing, in the exposed area of the image-recording layer, the image-recording layer cured by the exposure forms the printing ink receptive area having the oleophilic surface. On the other hand, in the unexposed area, the uncured image-recording layer is removed by dissolution or dispersion with the dampening water and/or printing ink supplied to reveal the hydrophilic surface in the area. As a result, the dampening water adheres on the revealed hydrophilic surface and the printing ink adheres to the exposed area of the image-recording layer, whereby printing is initiated.

While either the dampening water or printing ink may be supplied at first on the surface of lithographic printing plate precursor, it is preferred to supply the printing ink at first in view of preventing the dampening water from contamination with the component of the image-recording layer removed.

Thus, the lithographic printing plate precursor according to the invention is subjected to the on-press development on an offset printing machine and used as it is for printing a large number of sheets.

### EXAMPLES

The present invention will be described in more detail with reference to the following examples, but the invention should not be construed as being limited thereto.

### 1. Preparation of Lithographic Printing Plate Precursors (1) to (14)

### (1) Preparation of Support

An aluminum plate (material: JIS A 1050) having a thickness of 0.3 mm was subjected to a degreasing treatment at 50° C. for 30 seconds using a 10% by weight aqueous sodium aluminate solution in order to remove rolling oil on the surface thereof and then grained the surface thereof using three nylon brushes embedded with bundles of nylon bristle having a diameter of 0.3 mm and an aqueous suspension (specific gravity: 1.1 g/cm³) of pumice having a median size of 25 μm, followed by thorough washing with water. The plate was subjected to etching by immersing in a 25% by weight aqueous sodium hydroxide solution of 45° C. for 9 seconds, washed with water, then immersed in a 20% by weight aqueous nitric acid solution at 60° C. for 20 seconds, and washed with water. The etching amount of the grained surface was about 3 g/m².

Then, using an alternating current of 60 Hz, an electrochemical roughening treatment was continuously carried out on the plate. The electrolytic solution used was a 1% by weight aqueous nitric acid solution (containing 0.5% by weight of aluminum ion) and the temperature of electrolytic solution was 50° C. The electrochemical roughening treatment was conducted using an alternating current source, which provides a rectangular alternating current having a trapezoidal waveform such that the time TP necessary for the current value to reach the peak from zero was 0.8 msec and the duty ratio was 1:1, and using a carbon electrode as a counter electrode. A ferrite was used as an auxiliary anode. The current density was 30 A/dm² in terms of the peak value of the electric current, and 5% of the electric current flowing from the electric source was divided to the auxiliary anode. The quantity of electricity in the nitric acid electrolysis was 175 C/dm² in terms of the quantity of electricity when the aluminum plate functioned as an anode. The plate was then washed with water by spraying.

The plate was further subjected to an electrochemical roughening treatment in the same manner as in the nitric acid electrolysis above using as an electrolytic solution, a 0.5% by weight aqueous hydrochloric acid solution (containing 0.5% by weight of aluminum ion) having temperature of 50° C. and under the condition that the quantity of electricity was 50 C/dm² in terms of the quantity of electricity when the aluminum plate functioned as an anode. The plate was then washed with water by spraying.

The plate was then subjected to an anodizing treatment using as an electrolytic solution, a 15% by weight aqueous sulfuric acid solution (containing 0.5% by weight of aluminum ion) at a current density of 15 A/dm² to form a direct current anodized film of 2.5 g/m², washed with water and dried.

Thereafter, in order to ensure the hydrophilicity of the non-image area, the plate was subjected to silicate treatment using a 2.5% by weight aqueous sodium silicate No. 3 solution at 70° C. for 12 seconds. Subsequently, the plate was washed with water to obtain Support (1). The adhesion amount of Si was 10 mg/m². The center line average roughness (R^{a}) of the support was measured using a stylus having a diameter of 2 μm and found to be 0.51 μm.

### (2) Formation of Intermediate Layer (1)

Coating solution (1) for intermediate layer shown below was coated on Support (1) so as to have a dry coating amount of 28 mg/m² to prepare Intermediate layer (1).

### <Coating Solution (1) for Intermediate Layer>

| | |
|---|---|
| Compound (1) for intermediate layer having | 0.18 g |
| structure shown below | |
| Hydroxyethyliminodiacetic acid | 0.10 g |
| Methanol | 55.24 g |
| Water | 6.15 g |

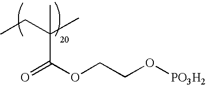

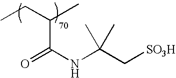

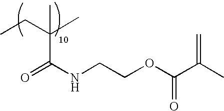

(Mw: 100,000)
Compound (1) for intermediate layer

### (3) Formation of Image-Recording Layer (1)

Coating solution (1) for image-recording layer having the composition shown below was coated on Intermediate layer (1) formed above by a bar and dried in an oven at 100° C. for 60 seconds to form Image-recording layer (1) having a dry coating amount of 1.0 g/m².

Coating solution (1) for image-recording layer was prepared by mixing Photosensitive solution (1) shown below with Microgel solution (1) shown below just before the coating, followed by stirring.

### <Photosensitive Solution (1)>

| | |
|---|---|
| Binder polymer (1) having structure shown | 0.24 g |
| below | |
| Infrared absorbing agent (1) having structure | 0.030 g |
| shown below | |
| Polymerization initiator (1) having structure | 0.162 g |
| shown below | |
| Polymerizable compound | 0.192 g |
| (Tris(acryloyloxyethyl) isocyanurate (NK | |
| Ester A-9300, produced by Shin-Nakamura | |
| Chemical Co., Ltd.)) | |
| Hydrophilic low molecular weight compound | 0.062 g |
| (Tris(2-hydroxyethyl) isocyanurate) | |
| Hydrophilic low molecular weight compound (1) | 0.050 g |
| having structure shown below | |
| Compound represented by formula (I) shown in | Amount shown |
| Table 1 | in Table 1 |
| Fluorine-based surfactant (1) having | 0.008 g |
| structure shown below | |
| Methyl ethyl ketone | 1.091 g |
| 1-Methoxy-2-propanol | 8.609 g |

### <Microgel Solution (1)>

| | |
|---|---|
| Microgel (1) shown below | 2.640 g |
| Distilled water | 2.425 g |

The structures of Binder polymer (1), Infrared absorbing agent (1), Polymerization initiator (1), Hydrophilic low molecular weight compound (1) and Fluorine-based surfactant (1) are shown below.

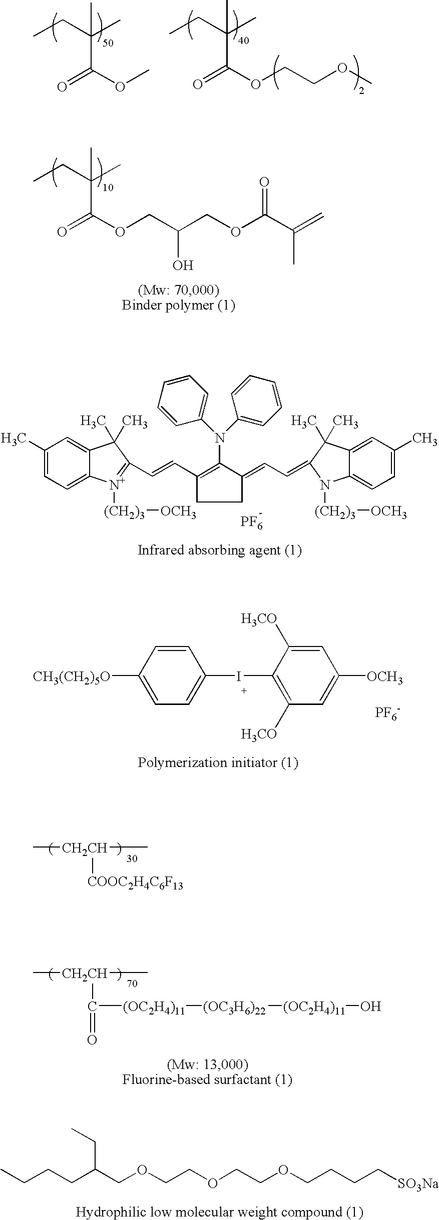

Microgel (1) was prepared in the following manner.

### <Preparation of Microgel (1)>

An oil phase component was prepared by dissolving 10 g of adduct of trimethylol propane and xylene diisocyanate (Takenate D-110N, produced by Mitsui Chemicals Polyurethanes, Inc.), 3.15 g of pentaerythritol triacrylate (SR444, produced by Nippon Kayaku Co., Ltd.) [Component (C)] and 0.1 g of Pionin A-41C (produced by Takemoto Oil & Fat Co., Ltd.) in 17 g of ethyl acetate. As an aqueous phase component, 40 g of a 4% by weight aqueous solution of PVA-205 was prepared. The oil phase component and the aqueous phase component were mixed and emulsified using a homogenizer at 12,000 rpm for 10 minutes. The resulting emulsion was added to 25 g of distilled water and stirred at room temperature for 30 minutes and then at 50° C. for 3 hours. The microgel liquid thus-obtained was diluted using distilled water so as to have the solid concentration of 15% by weight to prepare Microgel (1). The average particle size of the microgel was measured by a light scattering method and found to be 0.2 μm.

### (4) Formation of Protective Layer (1)

Coating solution (1) for protective layer having the composition shown below was coated on the image-recording layer described above by a bar and dried in an oven at 120° C. for 60 seconds to form Protective layer (1) having a dry coating amount of 0.15 g/m², thereby preparing Lithographic printing plate precursors (1) to (14), respectively.

### <Coating Solution (1) for Protective Layer>

| | |
|---|---|
| Dispersion of inorganic stratiform compound | 1.5 g |
| (1) shown below | |
| Aqueous 6% by weight solution of polyvinyl | 0.55 g |
| alcohol (CKS 50, sulfonic acid-modified, | |
| saponification degree: 99% by mole or more, | |
| polymerization degree: 300, produced by Nippon | |
| Synthetic Chemical Industry Co., Ltd.) | |
| Aqueous 6% by weight solution of polyvinyl | 0.03 g |
| alcohol (PVA-405, saponification degree: | |
| 81.5% by mole, polymerization degree: 500, | |
| produced by Kuraray Co., Ltd.) | |
| Aqueous 1% by weight solution of surfactant | 0.86 g |
| (Emalex 710, produced by Nihon Emulsion Co., | |
| Ltd.) | |
| Ion-exchanged water | 6.0 g |

### <Preparation of Dispersion of Inorganic Stratiform Compound (1)>

To 193.6 g of ion-exchanged water was added 6.4 g of synthetic mica (Somasif ME-100, produced by CO-OP Chemical Co., Ltd.) and the mixture was dispersed using a homogenizer until an average particle size (according to a laser scattering method) became 3 μm to prepare Dispersion of inorganic stratiform compound (1). The aspect ratio of the inorganic particle thus-dispersed was 100 or more.

TABLE 1
Lithographic printing plate precursors (1) to (14)

| | | Compound Represented by Formula (I) | | |
|---|---|---|---|---|
| Lithographic | | | Amount | |
| Printing | Image- | | of | Content in |
| Plate | Recording | Kind of | Compound | Image-Recording |
| Precursor | Layer | Compound | (g) | Layer (%) |
| (1) | (1) | Compound 1 | 0.002 | 0.16 |
| (2) | (1) | Compound 2 | 0.002 | 0.16 |
| (3) | (1) | Compound 3 | 0.002 | 0.16 |
| (4) | (1) | Compound 4 | 0.002 | 0.16 |
| (5) | (1) | Compound 5 | 0.002 | 0.16 |
| (6) | (1) | Compound 6 | 0.002 | 0.16 |
| (7) | (1) | Compound 7 | 0.002 | 0.16 |
| (8) | (1) | Compound 8 | 0.002 | 0.16 |
| (9) | (1) | Compound 5 | 0.050 | 4.10 |
| (10) | (1) | Compound 5 | 0.100 | 8.20 |
| (11) | (1) | None | 0 | 0 |
| (12) | (1) | Comparative | 0.002 | 0.16 |
| | | Compound 1 | | |
| (13) | (1) | Comparative | 0.002 | 0.16 |
| | | Compound 2 | | |
| (14) | (1) | Comparative | 0.002 | 0.16 |
| | | Compound 3 | | |

### Examples 1 to 10 and Comparative Examples 1 to 4

The ink receptive property, on-press development property after preservation and printing durability of Lithographic printing plate precursors (1) to (14) thus obtained were evaluated in the manner described below. The results obtained are shown in Table 2.

### (1) Ink Receptivity

Each of the lithographic printing plate precursors thus-obtained was exposed by Luxel Platesetter T-6000III equipped with an infrared semiconductor laser, produced by Fuji Film Co., Ltd. under the conditions of a rotational number of an outer surface drum of 1,000 rpm, laser output of 70% and resolution of 2,400 dpi. The exposed image contained a solid image and a 50% halftone dot chart of a 20 μm-dot FM screen.

The exposed lithographic printing plate precursor was mounted without undergoing development processing on a plate cylinder of a printing machine (Lithrone 26, produced by Komori Corp.). Using dampening water (Ecolity-2 (produced by Fuji Film Co., Ltd.)/tap water=2/98 (volume ratio)) and Values-G (N) Black Ink (produced by Dainippon Ink & Chemicals, Inc.), the dampening water and ink were supplied according to the standard automatic printing start method of Lithrone 26 to conduct on-press development and printing on 100 sheets of Tokubishi art paper (76.5 kg) at a printing speed of 10,000 sheets per hour.

A number of the printing papers required until ink density on the paper reached to the threshold state by the transfer of ink to the image area of the image-recording layer was measured as a number of papers for ink receptivity.

(2) On-Press Development Property after Preservation

The lithographic printing plate precursor was packed together with interleaf conditioned at 25° C. and 70% RH and backing cardboard having moisture content of 8% by aluminum kraft paper and preserved at 60° C. for 4 days.

Then, the lithographic printing plate precursor was exposed by Luxel Platesetter T-6000III equipped with an infrared semiconductor laser, produced by Fuji Film Co., Ltd. under the conditions of a rotational number of an outer surface drum of 1,000 rpm, laser output of 70% and resolution of 2,400 dpi. The exposed image contained a solid image and a 50% halftone dot chart of a 20 μm-dot FM screen.

The exposed lithographic printing plate precursor was mounted without undergoing development processing on a plate cylinder of a printing machine (Lithrone 26, produced by Komori Corp.). Using dampening water (Ecolity-2 (produced by Fuji Film Co., Ltd.))/tap water=2/98 (volume ratio)) and Values-G (N) Black Ink (produced by Dainippon Ink & Chemicals, Inc.), the dampening water and ink were supplied according to the standard automatic printing start method of Lithrone 26 to conduct on-press development and printing on 100 sheets of Tokubishi art paper (76.5 kg) at a printing speed of 10,000 sheets per hour.

A number of the printing papers required for reaching a state where the ink was not transferred to the printing paper in the non-image area after the completion of on-press development of the unexposed area of the image-recording layer on the printing machine was measured to evaluate the on-press development property after preservation.

### (3) Printing Durability

After performing the evaluation for the on-press development property after preservation, the printing was continued. As the increase in a number of printing papers, the image-recording layer was gradually abraded to cause decrease in the ink density on the printing paper. A number of printing papers wherein a value obtained by measuring a halftone dot area rate of the 50% halftone dot of FM screen on the printing paper using a Gretag densitometer decreased by 5% from the value measured on the 100^{th} paper of the printing was determined to evaluate the printing durability.

TABLE 2
Evaluation Results of Lithographic Printing Plate
Precursor

| | | | On-Press | |
|---|---|---|---|---|
| | | | Development | |
| | Lithographic | | Property | Printing |
| | Printing | Ink | after | Durability |
| | Plate | Receptivity | Preservation | (x 10⁵ |
| | Precursor | (sheets) | (sheets) | sheets) |
| Example 1 | (1) | 20 | 19 | 3.2 |
| Example 2 | (2) | 15 | 20 | 2.9 |
| Example 3 | (3) | 17 | 20 | 2.8 |
| Example 4 | (4) | 20 | 28 | 3.2 |
| Example 5 | (5) | 15 | 20 | 3.2 |
| Example 6 | (6) | 22 | 15 | 3.1 |
| Example 7 | (7) | 13 | 24 | 3.2 |
| Example 8 | (8) | 25 | 25 | 2.7 |
| Example 9 | (9) | 17 | 18 | 3.1 |
| Example 10 | (10) | 20 | 16 | 2.9 |
| Comparative | (11) | 50 | 30 | 3.0 |
| Example 1 | | | | |
| Comparative | (12) | 12 | 70 | 3.1 |
| Example 2 | | | | |
| Comparative | (13) | 25 | 60 | 3.0 |
| Example 3 | | | | |
| Comparative | (14) | 22 | 65 | 2.9 |
| Example 4 | | | | |

Comparative Compound 1: 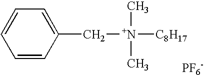
Comparative Compound 2: 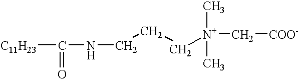
Comparative Compound 3:

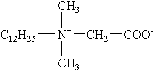

As is apparent from the results shown in Table 2, the lithographic printing plate precursor which achieves compatibility between good ink receptivity, on-press development property after preservation and printing durability and the plate making method thereof can be provided according to the invention.

### 2. Preparation of Lithographic Printing Plate Precursors (21) to (36)

### (1) Formation of Intermediate Layer (2)

Coating solution (2) for intermediate layer was prepared by adding the compound represented by formula (I) shown in Table 3 in the amount shown in Table 3 to Coating solution (1) for intermediate layer and coated on Support (1) so as to have a dry coating amount other than the compound represented by formula (I) of 28 mg/m² to prepare Intermediate layer (2).

### (2) Formation of Image-Recording Layer (2)

Lithographic printing plate precursors (21) to (36) were prepared in the same manner as in the preparation of Lithographic printing plate precursor (1) except for coating Coating solution (2) for image-recording layer having the composition shown below on Intermediate layer (2) in place of Coating solution (1) for image-recording layer.

Coating solution (2) for image-recording layer was prepared by mixing Photosensitive solution (2) shown below with Microgel solution (1) shown above just before the coating, followed by stirring.

### <Photosensitive Solution (2)>

| | |
|---|---|
| Binder polymer (1) having structure shown | 0.24 g |
| above | |
| Infrared absorbing agent (1) having structure | 0.030 g |
| shown above | |
| Polymerization initiator (1) having structure | 0.162 g |
| shown above | |
| Polymerizable compound | 0.192 g |
| (Tris(acryloyloxyethyl) isocyanurate (NK | |
| Ester A-9300, produced by Shin-Nakamura | |
| Chemical Co., Ltd.)) | |
| Hydrophilic low molecular weight compound | 0.062 g |
| (Tris(2-hydroxyethyl) isocyanurate) | |
| Hydrophilic low molecular weight compound (1) | 0.050 g |
| having structure shown above | |
| Compound represented by formula (I) shown in | Amount shown |
| Table 3 | in Table 3 |
| Fluorine-based surfactant (1) having | 0.008 g |
| structure shown above | |
| Methyl ethyl ketone | 1.091 g |
| 1-Methoxy-2-propanol | 8.609 g |

### Examples 11 to 22 and Comparative Examples 11 to 14

The ink receptive property, on-press development property after preservation and printing durability of Lithographic printing plate precursors (21) to (36) thus obtained were evaluated in the manner described above. The results obtained are shown in Table 42.

TABLE 3
Lithographic printing plate precursors (21) to (36)

| | Intermediate Layer (2) | | | Image-Recording Layer (2) | | |
|---|---|---|---|---|---|---|
| Lithographic | Compound Represented by Formula (I) | | | Compound Represented by Formula (I) | | |
| Printing | | Amount of | Content in | | Amount of | Content in |
| Plate | Kind of | Compound | Intermediate | Kind of | Compound | Image-Recording |
| Precursor | Compound | (g) | Layer (%) | Compound | (g) | Layer (%) |
| (21) | Compound 1 | 0.01 | 3.4 | None | 0 | 0 |
| (22) | Compound 2 | 0.01 | 3.4 | None | 0 | 0 |
| (23) | Compound 3 | 0.01 | 3.4 | None | 0 | 0 |
| (24) | Compound 4 | 0.01 | 3.4 | None | 0 | 0 |
| (25) | Compound 5 | 0.01 | 3.4 | None | 0 | 0 |
| (26) | Compound 6 | 0.01 | 3.4 | None | 0 | 0 |
| (27) | Compound 7 | 0.01 | 3.4 | None | 0 | 0 |
| (28) | Compound 8 | 0.01 | 3.4 | None | 0 | 0 |
| (29) | Compound 5 | 0.1 | 26 | None | 0 | 0 |
| (30) | Compound 5 | 0.2 | 42 | None | 0 | 0 |
| (31) | Compound 5 | 0.01 | 3.4 | Compound 5 | 0.002 | 0.16 |
| (32) | Compound 5 | 0.01 | 3.4 | Compound 5 | 0.05 | 4.1 |
| (33) | None | 0 | 0 | None | 0 | 0 |
| (34) | Comparative | 0.01 | 3.4 | None | 0 | 0 |
| | Compound 1 | | | | | |
| (35) | Comparative | 0.01 | 3.4 | None | 0 | 0 |
| | Compound 2 | | | | | |
| (36) | Comparative | 0.01 | 3.4 | None | 0 | 0 |
| | Compound 3 | | | | | |

TABLE 4
Evaluation Results of Lithographic Printing Plate
Precursor

| | | | On-Press | |
|---|---|---|---|---|
| | | | Development | |
| | Lithographic | | Property | Printing |
| | Printing | Ink | after | Durability |
| | Plate | Receptivity | Preservation | (×10⁵ |
| | Precursor | (sheets) | (sheets) | sheets) |
| Example 11 | (21) | 23 | 18 | 3.2 |
| Example 12 | (22) | 18 | 19 | 3.3 |
| Example 13 | (23) | 19 | 20 | 3.0 |
| Example 14 | (24) | 22 | 27 | 3.1 |
| Example 15 | (25) | 17 | 17 | 3.3 |
| Example 16 | (26) | 25 | 14 | 3.2 |
| Example 17 | (27) | 13 | 22 | 3.3 |
| Example 18 | (28) | 25 | 23 | 2.9 |
| Example 19 | (29) | 16 | 17 | 3.1 |
| Example 20 | (30) | 19 | 15 | 2.9 |
| Example 21 | (31) | 18 | 17 | 2.9 |
| Example 22 | (32) | 16 | 16 | 3.0 |
| Comparative | (33) | 40 | 30 | 2.3 |
| Example 11 | | | | |
| Comparative | (34) | 16 | 80 | 3.1 |
| Example 12 | | | | |
| Comparative | (35) | 30 | 65 | 3.0 |
| Example 13 | | | | |
| Comparative | (36) | 25 | 70 | 2.8 |
| Example 14 | | | | |

As is apparent from the results shown in Table 4, the lithographic printing plate precursor which achieves compatibility between good ink receptivity, on-press development property after preservation and printing durability and the plate making method thereof can be provided according to the invention. The similar results are also obtained when the compound represented by formula (I) is added to both the intermediate layer and the image-recording layer.

What is claimed is:

1. A lithographic printing plate precursor which comprises in the following order:
a support;
an image-recording layer comprising (A) an infrared absorbing agent, (B) a polymerization initiator and (C) a polymerizable compound; and
a protective layer,
wherein an unexposed area of the image-recording layer is capable of being removed with at least one of printing ink and dampening water on a printing machine, and the lithographic printing plate precursor comprises a compound represented by the following formula (I): 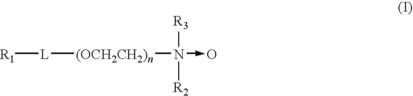
wherein R₁ represents an alkyl, alkenyl or aryl group having from 6 to 36 carbon atoms which may have a substituent, R₂ and R₃ each independently represents a methyl group, an ethyl group, a hydroxyethyl group or a hydroxypropyl group, L represents a single bond or a divalent connecting group, and n represents an integer of from 0 to 11.

2. The lithographic printing plate precursor as claimed in claim 1, which further comprises an intermediate layer between the support and the image-recording layer

3. The lithographic printing plate precursor as claimed in claim 1, wherein the image-recording layer comprises the compound represented by the formula (I).

4. The lithographic printing plate precursor as claimed in claim 2, wherein at least one of the intermediate layer and the image-recording layer comprises the compound represented by the formula (I).

5. The lithographic printing plate precursor as claimed in claim 1, wherein n in the formula (I) is 0.

6. The lithographic printing plate precursor as claimed in claim 2, wherein n in the formula (I) is 0.

7. The lithographic printing plate precursor as claimed in claim 3, wherein n in the formula (I) is 0.

8. The lithographic printing plate precursor as claimed in claim 4, wherein n in the formula (I) is 0.

9. The lithographic printing plate precursor as claimed in claim 1, wherein the protective layer comprises an inorganic particle.

10. The lithographic printing plate precursor as claimed in claim 2, wherein the protective layer comprises an inorganic particle.

11. The lithographic printing plate precursor as claimed in claim 3, wherein the protective layer comprises an inorganic particle.

12. The lithographic printing plate precursor as claimed in claim 4, wherein the protective layer comprises an inorganic particle.

13. The lithographic printing plate precursor as claimed in claim 9, wherein the inorganic particle is mica.

14. The lithographic printing plate precursor as claimed in claim 10, wherein the inorganic particle is mica.

15. The lithographic printing plate precursor as claimed in claim 11, wherein the inorganic particle is mica.

16. The lithographic printing plate precursor as claimed in claim 12, wherein the inorganic particle is mica.

17. The lithographic printing plate precursor as claimed in claim 4, wherein the intermediate layer comprises a copolymer containing (a1) a repeating unit having at least one ethylenically unsaturated bond and (a2) a repeating unit having at least one functional group capable of interacting with a surface of the support.
